(19) United States
(12) Patent Application Publication
(10) Pub. No.: US 2026/0296958 A1
(43) Pub. Date: Oct. 1, 2026

(54) PROCESSING SYSTEM AND METHOD FOR PROCESSING ULTRA-THIN GLASS, AND ULTRA-THIN GLASS CARRIER ASSEMBLY

(71) Applicant: MLMTEK Co., Ltd., Taoyuan City (TW)

(72) Inventor: YU-CHIA CHANG, New Taipei City (TW)

(21) Appl. No.: 19/529,038

(22) Filed: Feb. 3, 2026

Related U.S. Application Data
(60) Provisional application No. 63/754,496, filed on Feb. 5, 2025.

(51) Int. Cl. C03C 23/00; C03C 17/09

(52) U.S. Cl. CPC C03C 23/0025; C03C 17/09; C03C 2217/253; C03C 2217/258; C03C 2217/26; C03C 2218/151; C03C 2218/152; C03C 2218/154

(57) ABSTRACT

A processing system, an ultra-thin glass carrier assembly, and a method for processing an ultra-thin glass (UTG) substrate are disclosed. The system includes a laser processing module and a controller configured to control laser processing to extend beyond the UTG substrate to remove at least a portion of a reversible adhesive layer, thereby forming a through-hole having a bottom surface suitable for downstream processing without requiring additional adhesive removal steps. The ultra-thin glass carrier assembly includes a temporary carrier substrate, a reversible adhesive layer, and a UTG substrate with a through-hole extending through the UTG substrate and the reversible adhesive layer, and the bottom surface of the through-hole can expose the temporary carrier substrate. The method includes bonding the UTG substrate to a carrier, performing laser processing, and controlling the laser to penetrate beyond the UTG substrate to remove adhesive, enabling reliable metallization and other downstream processing.

### CROSS-REFERENCE TO RELATED PATENT APPLICATION

This application claims the benefit of priority to the U.S. Provisional Patent Application Ser. No. 63/754,496, filed on Feb. 5, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates generally to processing of ultra-thin glass (UTG) substrates, and more particularly to a processing system, method, and assembly for processing UTG substrates temporarily bonded to a carrier structure via a reversible adhesive layer, in which laser processing is controlled to extend beyond the UTG substrate to ensure reliable through-hole formation suitable for downstream processing.

### BACKGROUND OF THE DISCLOSURE

Ultra-thin glass (UTG) substrates, typically characterized by thicknesses of less than 100 μm, have attracted significant interest in advanced semiconductor packaging, flexible display, and high-frequency electronic applications.

Due to the mechanical fragility of UTG substrates, conventional processing approaches typically require temporary bonding of the UTG substrate to a rigid carrier substrate using a reversible adhesive layer.

Conventional teachings in the art have emphasized the importance of protecting the carrier substrate from damage during laser drilling or perforation operations. Such approaches typically configure laser parameters to terminate laser ablation precisely at or near the interface between the UTG substrate and the reversible adhesive layer, thereby preserving carrier reusability.

However, the present inventors have recognized and appreciated that such conservative approaches often result in incomplete removal of the reversible adhesive layer within the through-hole region. Residual adhesive material at the bottom of through-holes can adversely affect subsequent processing operations, including but not limited to metallization, seed layer deposition, electroplating, wet etching, and dry etching.

### SUMMARY OF THE DISCLOSURE

In response to the above-referenced technical inadequacy, the present disclosure provides a processing system, an ultra-thin glass carrier assembly, and a method for processing an ultra-thin glass substrate.

In order to solve the above-mentioned problems, one of the technical aspects adopted by the present disclosure is to provide a processing system for an ultra-thin glass substrate, which includes a laser processing module and a controller. The controller is operatively coupled to the laser processing module. The controller is configured to control the laser processing module to perform laser processing on the ultra-thin glass substrate that is carried by a temporary carrier substrate through a reversible adhesive layer. When the laser processing extends beyond the ultra-thin glass substrate, at least a portion of the reversible adhesive layer is removed through the laser processing.

In order to solve the above-mentioned problems, another one of the technical aspects adopted by the present disclosure is to provide an ultra-thin glass carrier assembly, which includes a temporary carrier substrate, a reversible adhesive layer and an ultra-thin glass substrate. The reversible adhesive layer is disposed on the temporary carrier substrate, and the ultra-thin glass substrate is disposed on the reversible adhesive layer. The ultra-thin glass substrate includes a through-hole extending through the ultra-thin glass substrate and the reversible adhesive layer, and wherein a bottom surface of the through-hole exposes at least a portion of the temporary carrier substrate.

In order to solve the above-mentioned problems, yet another one of the technical aspects adopted by the present disclosure is to provide a method for processing an ultra-thin glass substrate, which includes bonding an ultra-thin glass substrate to a temporary carrier substrate through a reversible adhesive layer; performing laser processing on the ultra-thin glass substrate while the ultra-thin glass substrate is bonded to the temporary carrier substrate; and controlling the laser processing such that the laser processing extends beyond the ultra-thin glass substrate to remove at least a portion of the reversible adhesive layer, thereby forming a through-hole having a bottom surface.

In certain embodiments, the controlled laser processing that extends beyond the ultra-thin glass substrate and into the reversible adhesive layer results in unexpected improvements in downstream processing yield and reliability, including improved metallization continuity, reduced via resistance variation, and enhanced adhesion of deposited conductive materials, as compared with laser processes configured to terminate at or near the interface between the ultra-thin glass substrate and the reversible adhesive layer.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of an ultra-thin glass carrier assembly prior to laser processing according to an embodiment of the present disclosure;

FIG. 2 is a schematic cross-sectional view showing laser processing extending beyond the ultra-thin glass substrate to penetrate a reversible adhesive layer according to the embodiment of the present disclosure;

FIG. 3 is a schematic cross-sectional view of a through-hole formed according to the embodiment of the present disclosure, showing a bottom surface exposing the temporary carrier substrate;

FIG. 4 is a functional block diagram of a processing system according to the embodiment of the present disclosure;

FIG. 5 is a flowchart of a method for processing the ultra-thin glass substrate according to the embodiment of the present disclosure;

FIG. 6 is a schematic cross-sectional view showing optional selective removal of a surface region of the temporary carrier substrate according to another embodiment of the present disclosure;

FIG. 7 is a schematic cross-sectional view showing the through-hole after metallization processing according to yet another embodiment of the present disclosure; and

FIG. 8 is a schematic cross-sectional view showing multiple through-hole type configurations for comparison.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. It should be noted that the examples provided in the following description are merely illustrative embodiments and are not intended to limit the scope of the present disclosure.

“Ultra-thin glass (UTG) substrate” refers to a glass substrate having a thickness of less than about 100 micrometers (μm), including but not limited to thicknesses of less than 50 μm, less than 30 μm, or in the range of about 10 μm to about 100 μm.

“Temporary carrier substrate” refers to a substrate configured to provide mechanical support to the UTG substrate during processing, and from which the UTG substrate is intended to be separated after completion of processing.

“Reversible adhesive layer” refers to an adhesive layer configured to temporarily bond the UTG substrate to the temporary carrier substrate, and which is removable or debondable by at least one of the following release mechanisms: ultraviolet (UV) irradiation, thermal treatment, laser irradiation, flash light irradiation, pulsed light irradiation, chemical solvent dissolution, and combinations thereof.

“Through-hole” refers to an aperture or an opening extending completely through the UTG substrate, including through-glass vias (TGVs) and other openings formed for purposes including electrical interconnection, fluid passage, and optical transmission.

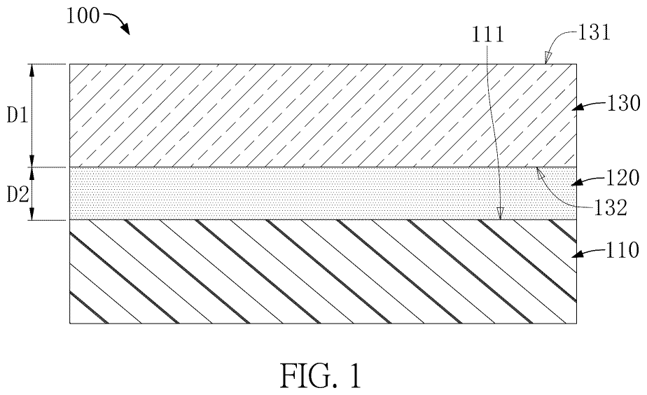

Referring to FIG. 1, an ultra-thin glass carrier assembly 100 according to an embodiment of the present disclosure is shown. The ultra-thin glass carrier assembly 100 includes a temporary carrier substrate 110 having an upper surface 111, a reversible adhesive layer 120 (or removable adhesive layer) disposed on the upper surface 111 of the temporary carrier substrate 110, and an ultra-thin glass substrate 130 (having a thickness in a range of 10 μm to 50 μm) disposed on the reversible adhesive layer 120. For example, the temporary carrier substrate 110 includes a material selected from the group consisting of glass, metal, ceramic, silicon, and high-temperature polymer material, and the temporary carrier substrate 110 has a thickness in a range of 0.3 mm to 2.0 mm.

The ultra-thin glass substrate 130 has an upper surface 131 and a lower surface 132. The depth thickness D1 of the ultra-thin glass substrate 130 is preferably in the range of about 10 μm to about 100 μm (such as any positive integer between 10 μm and 100 μm). The thickness D2 of the reversible adhesive layer 120 is preferably in the range of about 1 μm to about 50 μm (such as any positive integer between 1 μm and 50 μm).

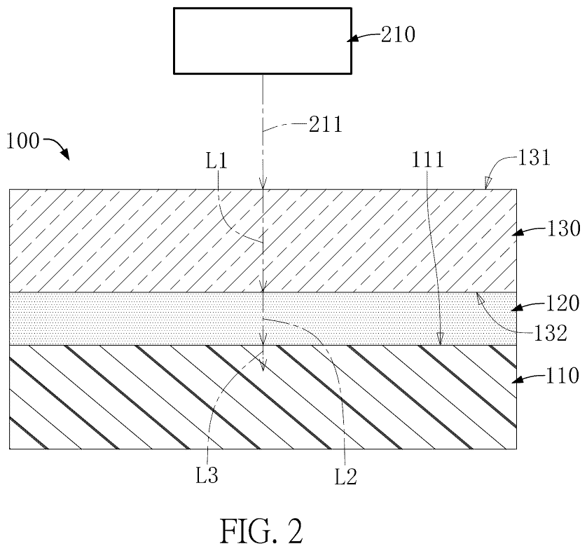

Referring to FIG. 2, a laser processing module 210 directs laser energy (or provides a laser light source 211, or a laser light beam) along a laser path including a first path segment L1 passing through the ultra-thin glass substrate 130, a second path segment L2 passing through the reversible adhesive layer 120, and a third path segment L3 passing through the upper surface 111 to the temporary carrier substrate 110. The processing zone indicates the region of controlled ablation.

In some embodiments, the depth to which the laser processing extends beyond the ultra-thin glass substrate 130 may be selectively or dynamically adjusted based on detected adhesive layer thickness variation, optical response during ablation, or predefined process windows.

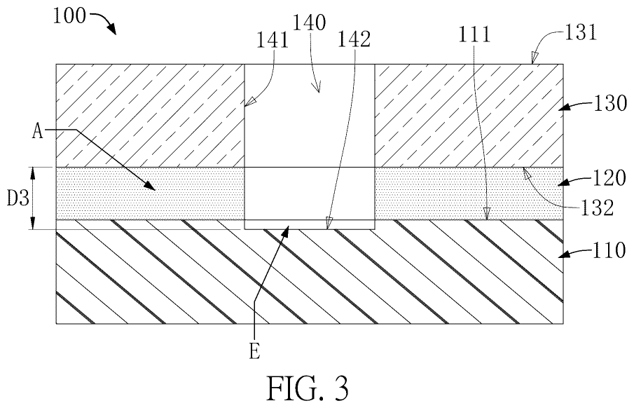

Referring to FIG. 3, the through-hole 140 is formed through the ultra-thin glass substrate 130 and the reversible adhesive layer 120. The through-hole 140 includes a sidewall 141 (or inner surrounding surface) and a bottom surface 142 that exposes a portion of the upper surface 111 of the temporary carrier substrate 110 (or passes through the reversible adhesive layer 120 to expose the temporary carrier substrate 110). The exposed zone E indicates the carrier surface exposed after adhesive removal (after removing a part of the reversible adhesive layer 120), while the adhesive zone A indicates the surrounding remaining adhesive of the reversible adhesive layer 120. The removed adhesive region corresponds to the portion of the reversible adhesive layer 120 that has been ablated during laser processing.

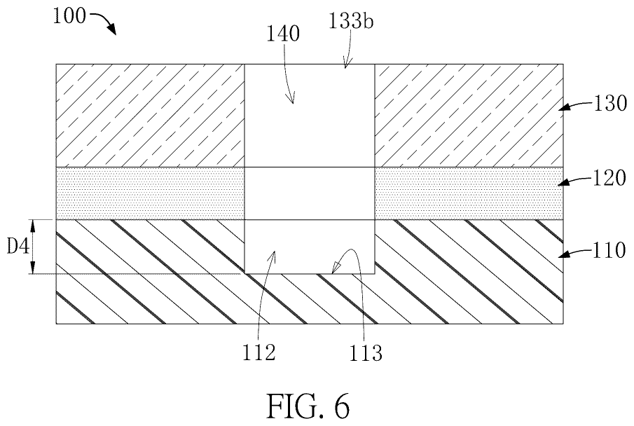

In contrast to conventional teachings which emphasize protection of the temporary carrier substrate, the present disclosure proposes that controlled laser penetration beyond the ultra-thin glass substrate 130, through the reversible adhesive layer 120, and to the carrier surface (the upper surface 111 of the temporary carrier substrate 110) ensures complete removal of adhesive residue at the through-hole bottom, thereby enabling reliable metallization and other downstream processing including, but not limited to, metallization, etching, and electrical interconnection. It has been unexpectedly found that sacrificing a minimal depth of the temporary carrier substrate 110 (as shown by depth D3 in FIG. 3 or depth D4 in FIG. 6) provides a “clean cut” mechanism that prevents the redeposition of carbonized adhesive residue, which typically occurs when laser energy is conservatively stopped at the adhesive interface. In some embodiments, the penetration depth D3 or D4 is less than 10 μm; in other embodiments, the penetration depth may vary depending on adhesive thickness, carrier material, and process requirements, and the present disclosure is not limited to any particular penetration depth range.

The present disclosure differs from approaches that rely on surface modification layers to control bonding forces. The reversible adhesive layer 120 is an organic adhesive layer and does not include a surface modification layer configured to control van der Waals or hydrogen bonding forces. The present disclosure does not rely on room-temperature mechanical separation for subsequent release of the ultra-thin glass substrate 130 from the temporary carrier substrate 110.

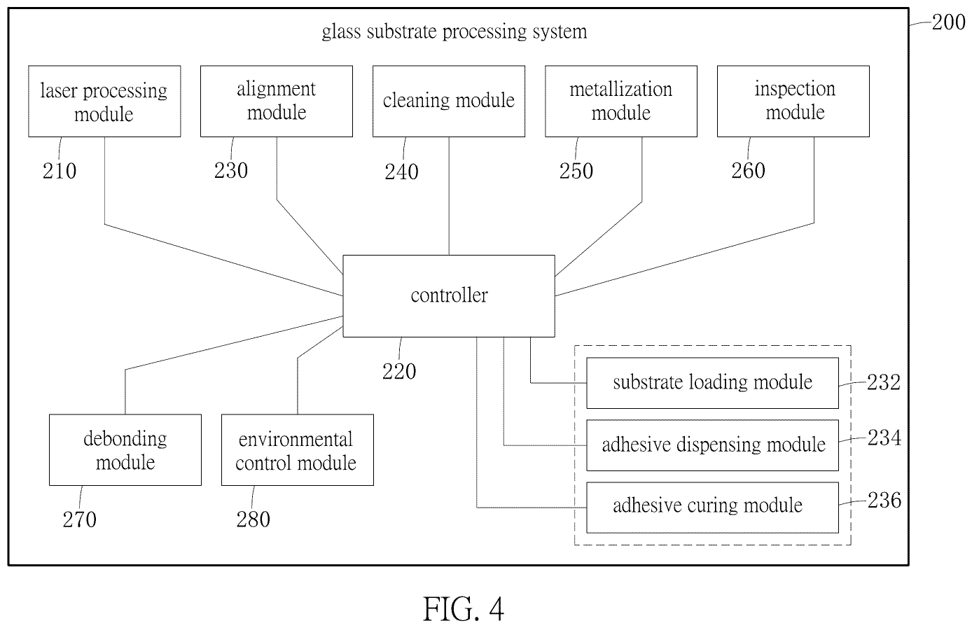

Referring to FIG. 4, a functional block diagram of a glass substrate processing system 200 is shown. The glass substrate processing system 200 includes a laser processing module 210 (or a laser generating module) configured for providing a laser source (having a wavelength in a range of 200 nm to 11 μm), a controller 220, an alignment module 230, a cleaning module 240, a metallization module 250, an inspection module 260, a debonding module 270 and an environmental control module 280. The laser processing module 210, the alignment module 230, the cleaning module 240, the metallization module 250, the inspection module 260, the debonding module 270 and the environmental control module 280 are electrically connected to the controller 220.

The controller 220 is configured to calculate and execute a processing depth that intentionally exceeds the combined thickness of the ultra-thin glass substrate 130 and the reversible adhesive layer 120. This control logic effectively prioritizes the quality of the through-hole bottom surface (i.e., freedom from residue) over the preservation of the temporary carrier substrate's surface, thereby ensuring the electrical reliability of subsequent interconnects.

The alignment module 230 is configured to precisely position the ultra-thin glass substrate 130 relative to the laser processing module 210, ensuring accurate placement of through-holes at predetermined locations. The cleaning module 240 is configured to perform post-laser cleaning operations, including but not limited to removal of debris, particles, and any residual carbonized material from the through-hole surfaces.

The metallization module 250 is configured to deposit conductive materials into the through-holes via process including seed layer deposition and electroplating operations. The inspection module 260 is configured to verify through-hole quality, including optical inspection, polarization-based inspection, and electrical characterization.

The debonding module 270 is configured to separate the processed ultra-thin glass substrate 130 from the temporary carrier substrate 110 after completion of through-hole processing and optional metallization. The debonding module 270 may employ at least one of: ultraviolet (UV) irradiation, thermal treatment, laser irradiation, flash light irradiation, pulsed light irradiation, and chemical solvent exposure to release the reversible adhesive layer 120.

The environmental control module 280 is configured to maintain controlled processing conditions during laser processing and subsequent operations. The environmental control module 280 may regulate at least one of temperature, humidity, atmospheric composition (including inert gas environment), particulate contamination levels, and pressure within the processing chamber.

The glass substrate processing system 200 further provides a pre-processing subsystem including a substrate loading module 232, an adhesive dispensing module 234 and an adhesive curing module 236. These pre-processing modules can be configured to prepare the ultra-thin glass carrier assembly 100 prior to laser processing.

The substrate loading module 232 is configured to receive and position the temporary carrier substrate 110 and the ultra-thin glass substrate 130 for subsequent bonding operations. The substrate loading module 232 may include handling mechanisms suitable for fragile ultra-thin glass materials, including but not limited to vacuum chucks, edge grippers, and Bernoulli handlers.

The adhesive dispensing module 234 is configured to apply the reversible adhesive layer 120 onto the temporary carrier substrate 110 prior to bonding with the ultra-thin glass substrate 130. The adhesive dispensing module 234 may employ at least one of: spin coating, slot-die coating, spray coating, screen printing, and inkjet dispensing to achieve uniform adhesive layer thickness D2 (as shown in FIG. 1).

The adhesive curing module 236 is configured to cure or partially cure the reversible adhesive layer 120 after the ultra-thin glass substrate 130 is placed on the reversible adhesive layer 120. The adhesive curing module 236 may employ at least one of: thermal curing, UV curing, and combined thermal-UV curing processes to achieve the desired bonding strength while maintaining reversibility for subsequent debonding.

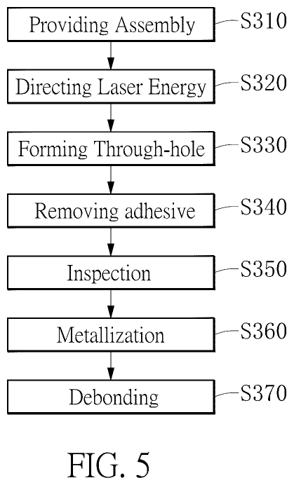

FIG. 5 illustrates a method for processing an ultra-thin glass substrate 130 includes mandatory steps S310 through S340 and optional steps S350 through S370.

At step S310 (Providing Assembly), the method begins by providing the ultra-thin glass carrier assembly 100 (as shown in FIG. 1), including the temporary carrier substrate 110, the reversible adhesive layer 120, and the ultra-thin glass substrate 130 bonded to the reversible adhesive layer 120.

At step S320 (Directing Laser Energy), the laser energy from the laser source 211 (as shown in FIG. 2) is directed toward the ultra-thin glass substrate 130. The laser processing module 210, under control of the controller 220, positions and focuses the laser beam at predetermined through-hole locations.

At step S330 (Forming Through-hole), the through-hole 140 is formed through the ultra-thin glass substrate 130. Crucially, step S330 is integrated with step S340 (Removing adhesive), as the laser processing is controlled to remove a part of the reversible adhesive layer 120 in-situ during the hole formation. Because the laser penetrates to the temporary carrier substrate 110, the resulting exposed zone E (as seen in FIG. 3) is substantially free of organic residue.

At step S340 (Removing adhesive), the reversible adhesive layer 120 within the through-hole region is removed by the controlled laser penetration. Consequently, the method for processing the ultra-thin glass substrate 130 may optionally exclude separate aggressive desmear or plasma ashing steps (e.g., O₂ plasma descum) that are typically required in prior art processes to clean the hole bottom, thereby reducing process time and equipment cost.

At optional step S350 (Inspection), the formed through-holes 140 are inspected to verify quality and conformance to specifications. The inspection module 260 (as shown in FIG. 4) may perform at least one of: optical inspection to detect physical defects, dimensional measurements, and sidewall quality; polarization-based inspection to assess residual stress and material integrity; cross-sectional analysis using scanning electron microscopy (SEM) or focused ion beam (FIB) techniques; and electrical characterization to verify continuity and resistance of metallized vias.

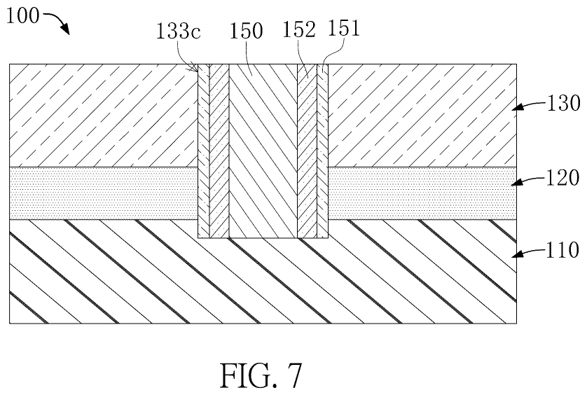

At optional step S360 (Metallization), the conductive material 150 (as shown in FIG. 7) is deposited in the through-holes to form electrically conductive vias. The metallization module 250 may perform a seed layer 151 (as shown in FIG. 7) deposition followed by electroplating of a plated metal layer 152 (as shown in FIG. 7). The seed layer 151 may include at least one of: titanium, titanium-tungsten, chromium, and copper deposited by sputtering, evaporation, or chemical vapor deposition. The plated metal layer 152 may comprise at least one of: copper, gold, nickel, and tin deposited by electroplating or electroless plating.

At optional step S370 (Debonding), the processed UTG substrate 130 is separated from the temporary carrier substrate 110. The debonding module 270 applies at least one release mechanism to the reversible adhesive layer 120, including: ultraviolet (UV) irradiation to decompose UV-sensitive adhesive components; thermal treatment to reduce adhesive bonding strength; laser irradiation directed through the carrier temporary substrate 110 to ablate the adhesive interface; flash light or pulsed light irradiation to rapidly heat and release the adhesive; and chemical solvent exposure to dissolve or swell the adhesive material.

In practical manufacturing environments involving ultra-thin glass substrates temporarily bonded to carrier substrates, the formation of through-holes suitable for downstream processing is typically evidenced by externally observable characteristics. Such characteristics may include, without limitation, the ability of a bottom surface of the through-hole to accept continuous metallization, the formation of electrically conductive vias exhibiting low and consistent resistance, and the absence of detectable organic residue at the through-hole bottom when analyzed using, for example, cross-sectional, spectroscopic, or electrical characterization techniques, or other equivalent analytical methods.

The present disclosure proposes that the presence of such externally observable characteristics is indicative of laser processing that extends beyond the ultra-thin glass substrate 130 and into the reversible adhesive layer 120. Incomplete penetration into the reversible adhesive layer 120 would otherwise inhibit reliable metallization, electrical interconnection, or multilayer build-up, due to residual adhesive material remaining at the through-hole bottom surface.

It has further been observed that such characteristics are not attributable to incidental cleaning effects or post-processing alone. Processes relying solely on post-laser chemical cleaning, plasma treatment, or solvent exposure, without controlled laser penetration into the reversible adhesive layer 120, have been found insufficient to consistently produce through-holes exhibiting the aforementioned externally observable characteristics under volume manufacturing conditions.

Referring to FIG. 6 and FIG. 7, advanced configurations of the through-hole are shown. In FIG. 6, a through-hole 133b (Type B) is shown where the laser processing has created a surface recess region 112 in the temporary carrier substrate 110, having a recess bottom surface 113. The depth D4 represents a safety margin that ensures 100% removal of the reversible adhesive layer 120 across the entire diameter of the through-hole 140. FIG. 7 shows a through-hole 133c (Type C) after metallization, where a seed layer 151 and a plated metal layer 152 (for forming a conductive material 150) are deposited. The clean bottom surface achieved by the present method allows the seed layer 151 to be deposited directly onto the exposed carrier or recess bottom without interfacial impedance from residual adhesive.

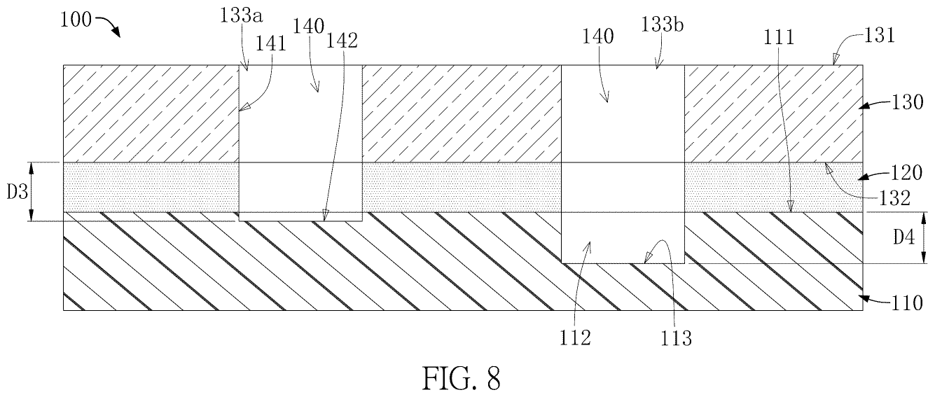

FIG. 8 provides a comparison of multiple through-hole types. Type A (a through-hole 133a) represents a planar bottom configuration where laser ablation stops exactly at the upper surface 111 of the temporary carrier substrate 110. Type B (the through-hole 133b) represents a recessed bottom configuration. Both configurations fall within the scope of the present disclosure, as both share the common technical feature of the laser processing extending completely through the reversible adhesive layer 120 to expose the carrier material, distinct from prior art methods that leave a thin layer of adhesive to protect the carrier.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A processing system for an ultra-thin glass substrate, comprising:
a laser processing module; and
a controller operatively coupled to the laser processing module;
wherein the controller is configured to control the laser processing module to perform laser processing on the ultra-thin glass substrate that is carried by a temporary carrier substrate through a reversible adhesive layer;
wherein, when the laser processing extends beyond the ultra-thin glass substrate, at least a portion of the reversible adhesive layer is removed through the laser processing.

2. The processing system according to claim 1, wherein the ultra-thin glass substrate is processed by the laser processing to form a through-hole having a bottom surface substantially free of adhesive residue.

3. The processing system according to claim 2, further comprising
a substrate loading module electrically connected to the controller, wherein the substrate loading module is configured to receive and position the temporary carrier substrate and the ultra-thin glass substrate;
an adhesive dispensing module electrically connected to the controller, wherein the adhesive dispensing module is configured to apply the reversible adhesive layer onto the temporary carrier substrate prior to bonding with the ultra-thin glass substrate;
an adhesive curing module electrically connected to the controller, wherein the adhesive curing module is configured to cure the reversible adhesive layer after the ultra-thin glass substrate is placed on the reversible adhesive layer;
a cleaning module electrically connected to the controller, wherein the cleaning module is configured to perform post-laser cleaning;
a metallization module electrically connected to the controller, wherein the metallization module is configured to deposit conductive materials into the through-hole;
an inspection module electrically connected to the controller, wherein the inspection module is configured to verify the quality of the through-hole;
a debonding module electrically connected to the controller, wherein the debonding module is configured to separate the ultra-thin glass substrate from the temporary carrier substrate; and
an environmental control module electrically connected to the controller, wherein the environmental control module is configured to maintain controlled processing conditions during laser processing and subsequent operations.

4. An ultra-thin glass carrier assembly, comprising:
a temporary carrier substrate;
a reversible adhesive layer disposed on the temporary carrier substrate; and
an ultra-thin glass substrate disposed on the reversible adhesive layer;
wherein the ultra-thin glass substrate includes a through-hole extending through the ultra-thin glass substrate and the reversible adhesive layer, and wherein a bottom surface of the through-hole exposes at least a portion of the temporary carrier substrate.

5. The ultra-thin glass carrier assembly according to claim 4,
wherein the ultra-thin glass substrate has a thickness of less than 100 micrometers; and
wherein the reversible adhesive layer has a thickness in a range of 1 micrometer to 50 micrometers.

6. The ultra-thin glass carrier assembly according to claim 4, wherein the bottom surface of the through-hole is substantially free of adhesive residue.

7. The ultra-thin glass carrier assembly according to claim 4, wherein the temporary carrier substrate includes a surface recess region at the bottom surface of the through-hole.

8. The ultra-thin glass carrier assembly according to claim 4, further comprising a conductive material disposed in the through-hole, and the conductive material including a seed layer and a plated metal layer connected to the seed layer.

9. The ultra-thin glass carrier assembly according to claim 4, wherein the through-hole has a sidewall extending from an upper surface of the ultra-thin glass substrate to the bottom surface of the ultra-thin glass substrate.

10. The ultra-thin glass carrier assembly according to claim 4, wherein the temporary carrier substrate includes a material selected from the group consisting of glass, metal, ceramic, silicon, and high-temperature polymer material.

11. A method for processing an ultra-thin glass substrate, comprising:
bonding an ultra-thin glass substrate to a temporary carrier substrate through a reversible adhesive layer;
performing laser processing on the ultra-thin glass substrate while the ultra-thin glass substrate is bonded to the temporary carrier substrate; and
controlling the laser processing such that the laser processing extends beyond the ultra-thin glass substrate to remove at least a portion of the reversible adhesive layer, thereby forming a through-hole having a bottom surface.

12. The method according to claim 11, wherein the process of controlling the laser processing includes directing a laser light source along a laser path extending to a surface of the temporary carrier substrate through the ultra-thin glass substrate and the reversible adhesive layer.

13. The method according to claim 11, wherein the process of performing the laser processing includes using at least one of: CO2 laser, UV laser, femtosecond laser, and picosecond laser.

14. The method according to claim 11, wherein the laser processing penetrates to a depth beyond the ultra-thin glass substrate, the depth being sufficient to substantially remove the reversible adhesive layer at the through-hole bottom.

15. The method according to claim 11, further comprising:
inspecting the through-hole through an optical inspection or a polarization-based inspection after forming the through-hole;
depositing a conductive material in the through-hole;
debonding the ultra-thin glass substrate from the temporary carrier substrate; and
cleaning the through-hole after laser processing.

16. The method according to claim 11, wherein the bottom surface of the through-hole exposes a continuous region of the temporary carrier substrate.

17. The method according to claim 11, wherein the reversible adhesive layer is configured to be removed by at least one of: ultraviolet irradiation, thermal treatment, laser irradiation, flash light irradiation, pulsed light irradiation, and solvent exposure.

18. The method according to claim 11, wherein the laser processing uses a laser source having a wavelength in a range of 200 nm to 11 μm.

19. The method according to claim 11, wherein the ultra-thin glass substrate has a thickness in a range of 10 μm to 50 μm.

20. The method according to claim 11, wherein the temporary carrier substrate has a thickness in a range of 0.3 mm to 2.0 mm.
